(19) United States
(12) Patent Application Publication
(10) Pub. No.: US 2025/0164533 A1
(43) Pub. Date: May 22, 2025

(54) SEMICONDUCTOR DEVICE, TEST APPARATUS AND METHOD FOR TESTING SEMICONDUCTOR CHIP

(71) Applicant: SK hynix Inc., Gyeonggi-do (KR)

(72) Inventor: Chul Hee OH, Gyeonggi-do (KR)

(21) Appl. No.: 18/619,170

(22) Filed: Mar. 28, 2024

(30) Foreign Application Priority Data
Nov. 16, 2023 (KR) 10-2023-0159153

(51) Int. Cl. G01R 23/02; G01R 31/3183; G01R 31/3185

(52) U.S. Cl. CPC G01R 23/02; G01R 31/3183; G01R 31/318594

(57) ABSTRACT

In an embodiment of the present disclosure, the frequency of a test signal and the speed of a test for a second circuit block to be tested are adjusted based on a measurement value for a first circuit block which represents the characteristics of a semiconductor device. Therefore, the efficiency of a test on the semiconductor device may be improved by reducing a time required for the entire test while maintaining the stability and performance of the test.

### CROSS-REFERENCE TO RELATED APPLICATION

The present application claims priority under 35 U.S.C. § 119 (a) to Korean Patent Application No. 10-2023-0159153 filed on Nov. 16, 2023, which is incorporated herein by reference in its entirety.

### BACKGROUND

### 1. Technical Field

Various embodiments of the present disclosure generally relate to a semiconductor device, a test apparatus and a method for testing a semiconductor chip.

### 2. Related Art

When the manufacturing process of a semiconductor chip is completed, a test on the semiconductor chip may be performed to check whether the semiconductor chip normally operates or to determine the performance of the semiconductor chip.

In general, a test on a semiconductor chip may be performed in such a way to input test data to the semiconductor chip and compare a value outputted from the semiconductor chip in response to the test data with a preset prediction value or a prediction result.

The test on a semiconductor chip may be performed in a predetermined way, and a time required to test the semiconductor chip may increase. Measures capable of reducing a time required for a test on a semiconductor chip while securing the accuracy of the test is in demand.

### SUMMARY

Various embodiments of the present disclosure are directed to measures capable of reducing a time required to test a semiconductor chip while securing the performance and accuracy of a test on the semiconductor chip.

In an embodiment of the present disclosure, a test apparatus may include a sampling circuit configured to output a first test input signal during a first test period to a first circuit block included in each of a plurality of semiconductor devices, and receive a first test output signal outputted from the first circuit block; and a test control circuit configured to output a second test input signal having a test frequency set for each of the plurality of semiconductor devices corresponding to an output frequency or an output current value of the first test output signal, during a second test period to a second circuit block included in each of the plurality of semiconductor devices, and perform a test on each of the plurality of semiconductor devices.

In an embodiment of the present disclosure, a semiconductor device may include a first circuit block configured to receive a first test input signal and output a first test output signal during a first test period; and a second circuit block configured to receive a second test input signal which has a test frequency set corresponding to an output frequency or an output current value of the first test output signal, during a second test period.

In an embodiment of the present disclosure, a method for testing a semiconductor chip may include outputting a first test input signal during a first test period to a first circuit block included in each of a plurality of semiconductor devices; receiving a first test output signal outputted from the first circuit block; classifying each of the plurality of semiconductor devices into one of N number of preset groups based on an output frequency or an output current value of the first test output signal; and outputting a second test input signal which has a test frequency set for each of the N number of preset groups, during a second test period to a second circuit block included in each of the plurality of semiconductor devices, where N is a natural number 2 or more.

According to the embodiments of the present disclosure, an optimized test may be performed by reflecting the characteristics of a semiconductor chip, and a time required for the test may be reduced while securing the performance of the test on the semiconductor chip.

### BRIEF DESCRIPTION OF THE DRAWINGS

FIG. 1 is a diagram illustrating a configuration of a test apparatus and a semiconductor device in accordance with an embodiment of the present disclosure.

FIG. 2 is a diagram illustrating a detailed configuration of a first circuit block included in the semiconductor device shown in FIG. 1 in accordance with an embodiment of the present disclosure.

FIG. 3 is a diagram illustrating a detailed configuration of a second circuit block included in the semiconductor device shown in FIG. 1 in accordance with an embodiment of the present disclosure.

FIG. 4 is a timing diagram illustrating test input signals inputted during respective test periods for respective semiconductor chips in accordance with an embodiment of the present disclosure.

FIGS. 5 to 8 are diagrams for describing a method for testing a semiconductor chip in accordance with an embodiment of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all meanings of the term “can”.

Hereinafter, various embodiments of the present disclosure will be described in detail with reference to accompanying drawings.

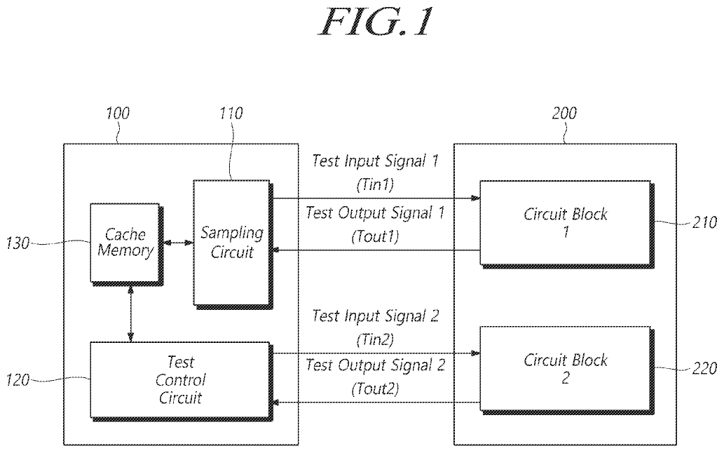

FIG. 1 is a diagram illustrating an example of the schematic configurations of a test apparatus 100 and a semiconductor device 200 in accordance with an embodiment of the present disclosure.

The test apparatus 100 may be a device which performs a test on the semiconductor device 200 at a wafer level or a package level. The test apparatus 100 may be a device which is implemented in hardware or a device which is implemented in software.

The semiconductor device 200 may be a non-memory semiconductor such as a system-on-chip or may be a memory semiconductor such as a DRAM and a NAND flash. The semiconductor device 200 may be one of various semiconductor devices on which tests are performed.

Referring to FIG. 1, the test apparatus 100 may include a sampling circuit 110, a test control circuit 120 and a cache memory 130. The semiconductor device 200 may include a first circuit block (circuit block 1) 210 and a second circuit block (circuit block 2) 220.

In order to perform a test on the semiconductor device 200, the test apparatus 100 may output a test input signal to the semiconductor device 200 and receive a test output signal from the semiconductor device 200. In order to improve the efficiency of the test on the semiconductor device 200, the test apparatus 100 may measure the characteristics of the semiconductor device 200 before performing the test.

For example, the sampling circuit 110 included in the test apparatus 100 may output a first test input signal (test input signal 1, Tin1) to the first circuit block 210 included in the semiconductor device 200 during a first test period. The sampling circuit 110 may receive a first test output signal (test output signal 1, Tout1) outputted from the first circuit block 210 in response to the first test input signal during the first test period.

The first test input signal may be, for example, a test clock signal which has an input frequency. Alternatively, the first test input signal may be a signal which has a preset voltage value or current value.

The first test output signal may be a signal which is outputted by the first circuit block 210 having received the test clock signal, and may be a signal which has an output frequency the same as or different from the input frequency. Alternatively, the first test output signal may be a signal which has a voltage value or a current value the same as or different from the voltage value or the current value of the test input signal.

The sampling circuit 110 may store the value of the output frequency, the voltage value or the current value according to the first test output signal received from the first circuit block 210, in the cache memory 130. A characteristic value according to the first test output signal of the first circuit block 210, which is stored in the cache memory 130, may be used when performing the test by the test control circuit 120.

The first circuit block 210 included in the semiconductor device 200 may be a block which may reflect the characteristics of the semiconductor device 200 or another circuit block included in the semiconductor device 200, as a test target.

For example, the first circuit block 210 may be a circuit block including a process detector which is included in a system-on-chip and is used to check the process characteristics of the corresponding system-on-chip.

Depending on the process characteristics of the semiconductor device 200, the frequency of a signal outputted in response to a signal inputted to the process detector may be different.

Since the output frequency of the first test output signal outputted in response to the first test input signal inputted to the process detector may reflect the characteristics of the semiconductor device 200, by performing the test using a test signal set based on the output frequency, an optimized test may be performed on the corresponding semiconductor device 200.

Alternatively, the first circuit block 210 may be an electrical parameter measurement (on-die EPM) circuit block included in a memory semiconductor such as a NAND flash. By using the current value or the voltage value of the first test output signal outputted in response to the first test input signal inputted to the electrical parameter measurement circuit block, the test that reflects the characteristics of the semiconductor device 200 may be performed.

Describing, as an example, a case where the first circuit block 210 included in the semiconductor device 200 is a process detector, the sampling circuit 110 may output a first test input signal having an input frequency to the first circuit block 210, and may receive a first test output signal having an output frequency from the first circuit block 210.

The test control circuit 120 included in the test apparatus 100 may output a second test input signal having a test frequency set based on the output frequency of the first test output signal to the second circuit block 220 included in the semiconductor device 200 during a second test period.

The test control circuit 120 may receive, during the second test period, a second test output signal which is outputted by the second circuit block 220 in response to the second test input signal. The test control circuit 120 may perform the test on the semiconductor device 200 by comparing the second test output signal with a preset prediction value.

The test control circuit 120 may set the test frequency according to the characteristics of a test type or the characteristics of a circuit block being a test target.

For example, the second circuit block 220 included in the semiconductor device 200 may be a circuit block for a scan test. The characteristics of the scan shift speed of the circuit block for a scan test may have a tendency similar to the output frequency of the first test output signal which is outputted from the process detector.

For example, the test control circuit 120 may set the test frequency to be proportional to the output frequency of the first test output signal.

When the output frequency of the first test output signal is great, the test control circuit 120 may output, to the second circuit block 220, the second test input signal which has the test frequency set to be high. A scan test may be performed at a fast scan shift speed.

When the output frequency of the first test output signal is small, the test control circuit 120 may output, to the second circuit block 220, the second test input signal which has the test frequency set to be low. A scan test may be performed at a slow scan shift speed.

As the case may be, the test control circuit 120 may classify the semiconductor device 200 into one of preset groups depending on the output frequency of the first test output signal, and may set the test frequency based on the corresponding group.

For example, the test control circuit 120 may classify the semiconductor device 200 into one of N (where N is a natural number 2 or more) number of groups depending on the output frequency of the first test output signal. A test frequency may be set for each of the N number of groups. As the second test input signal according to the test frequency set for a group to which the semiconductor device 200 belongs is inputted to the semiconductor device 200, the test may be performed.

In this way, for the semiconductor device 200 in which the output frequency of the first test output signal is small, the test may be performed using the second test input signal which has a low test frequency. The scan test may be performed at a relatively slow scan shift speed, and it is possible to prevent the semiconductor device 200 from being damaged when the scan test is performed at a fast scan shift speed.

For the semiconductor device 200 in which the output frequency of the first test output signal is great, the test may be performed using the second test input signal which has a high test frequency. A scan test may be performed at a relatively fast scan shift speed. A time required for the test on the corresponding semiconductor device 200 may be reduced. A scan test may be performed at a different scan shift speed depending on the characteristics of the semiconductor device 200, and an overall test time may be reduced.

Similarly, when the first circuit block 210 included in the semiconductor device 200 is an electrical parameter measurement circuit block which is included in a memory semiconductor, the test control circuit 120 may set the test frequency to be proportional to the current value or the voltage value of the first test output signal.

The test control circuit 120 may classify the semiconductor device 200 into one of N number of groups depending on the current value or the voltage value of the first test output signal, and may perform the test using the second test input signal having a test frequency which is set for the corresponding group.

The test control circuit 120 may adjust the scan shift speed of a scan test based on the current value or the voltage value of the first test output signal outputted from the electrical parameter measurement circuit block. The test control circuit 120 may perform an optimized scan test while reducing a time required for the scan test.

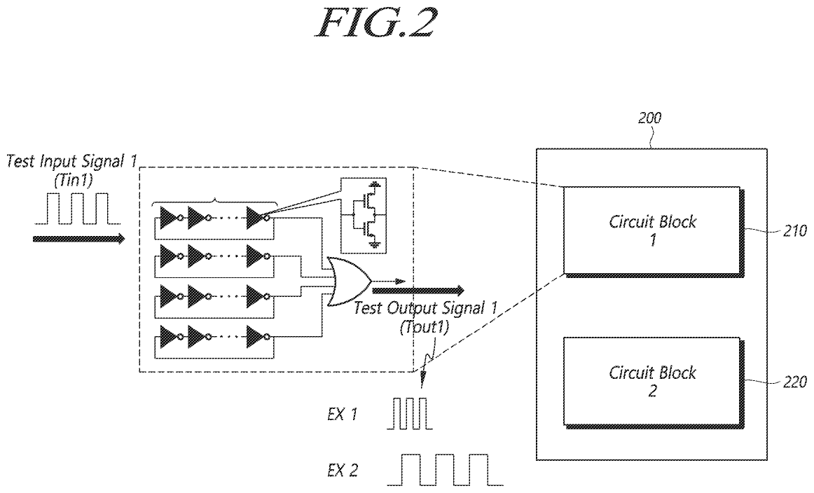

FIG. 2 is a diagram illustrating a detailed configuration of the first circuit block 210 included in the semiconductor device 200 in accordance with an embodiment of the present disclosure.

Referring to FIG. 2, a case where the first circuit block 210 included in the semiconductor device 200 is a process detector circuit block is illustrated as an example. For example, the process detector circuit block may be configured with a ring oscillator.

The first circuit block 210 may receive a first test input signal having an input frequency from the sampling circuit 110. The first test input signal may be a test clock signal.

The first circuit block 210 may output a first test output signal having an output frequency to the sampling circuit 110.

As in an example shown in EX 1, the output frequency of the first test output signal may be greater than the input frequency of the first test input signal. Alternatively, as in an example shown in EX 2, the output frequency of the first test output signal may be less than the input frequency of the first test input signal.

The test frequency of a second test input signal supplied to the second circuit block 220 may be determined depending on the output frequency of the first test output signal. The second test input signal which has a different test frequency for each semiconductor device 200 may be inputted.

For example, when a plurality of semiconductor devices to be tested are referred to as test semiconductors, a test may be performed as the second test input signal having a high test frequency is inputted to a first test semiconductor which outputs the first test output signal as in the example shown in EX 1. A test may be performed as the second test input signal having a low test frequency is inputted to a second test semiconductor which outputs the first test output signal as in the example shown in EX 2.

The input frequency of the first test input signal inputted to the first test semiconductor may be the same as the input frequency of the first test input signal inputted to the second test semiconductor.

The input frequency of the second test input signal inputted to the first test semiconductor may be different from the input frequency of the second test input signal inputted to the second test semiconductor. The input frequency of the second test input signal inputted to the first test semiconductor may be greater than the input frequency of the second test input signal inputted to the second test semiconductor.

The length of a first test period during which the first test input signal is inputted to the first test semiconductor may be the same as the length of a first test period during which the first test input signal is inputted to the second test semiconductor.

The length of a second test period during which the second test input signal is inputted to the first test semiconductor may be different from the length of a second test period during which the second test input signal is inputted to the second test semiconductor. The length of the second test period during which the second test input signal is inputted to the first test semiconductor may be shorter than the length of the second test period during which the second test input signal is inputted to the second test semiconductor.

Tests may be performed according to the second test input signals which reflect the characteristics of the first test semiconductor and the second test semiconductor. In a case where the second circuit block 220 to which the second test input signal is inputted is a circuit block for a scan test, a scan shift speed may be adjusted.

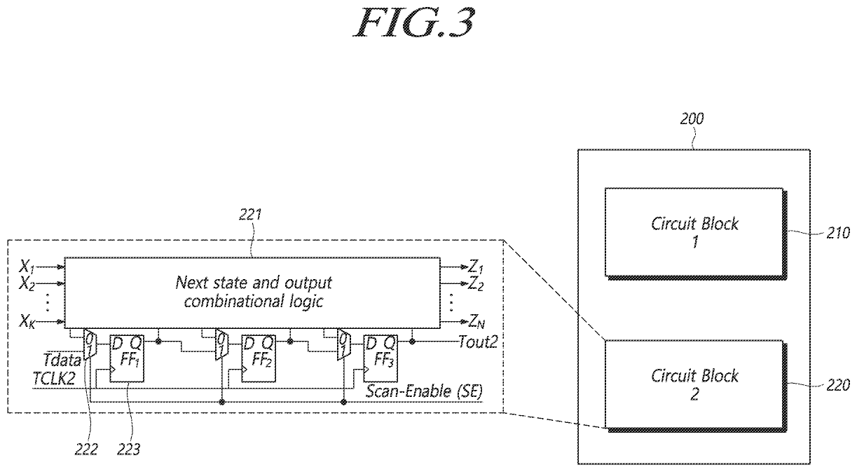

FIG. 3 is a diagram illustrating a detailed configuration of the second circuit block 220 included in the semiconductor device 200 in accordance with an embodiment of the present disclosure.

Referring to FIG. 3, the second circuit block 220 may include a next state and output combinational logic (hereinafter “a combinational circuit”) 221, multiplexers 222 and flip-flops 223. A plurality of flip-flops 223 may configure a sequential circuit. Each flip-flop 223 may be implemented in various ways, and the example shown in FIG. 3 illustrates a scan flip-flop 223 using a multiplexer 222.

The second circuit block 220 may include, for example, a main input port, a main output port, a scan activation port, a scan input port, a clock input port, a scan output port, and so on. The scan activation port and the clock input port may be connected to the flip-flop 223. Each flip-flop 223 may be connected to the combinational circuit 221 to output a value stored in each flip-flop 223 to the combinational circuit 221 and receive a value outputted from the combinational circuit 221.

For example, a scan test may be performed using a signal inputted to the scan input port and a signal outputted from the scan output port. For example, a scan-enable (SE) signal may be input to the multiplexer 222 for the scan test. A signal which is output from the multiplexer 222 and input to the flip-flop 223 may be changed according to the scan-enable signal. A signal which is output from the flip-flop 223 may be changed, and the scan test can be performed. For example, a test clock signal (TCLK2) may be inputted to the clock input port. The test frequency of the test clock signal may be a frequency which is set based on the output frequency of the first test output signal outputted from the process detector circuit block.

The test frequency of the test clock signal may be set to correspond to each of the cases EX1 and EX2 shown in FIG. 2.

The test clock signal having the test frequency may be inputted to the clock input port, and a test data signal (Tdata) according to the test frequency may be inputted to the scan input port. The test data signal may be a signal which is synchronized with the test frequency of the test clock signal.

In a case where the second circuit block 220 is a circuit block for a scan test, the second test input signal including the test clock signal and the test data signal may be inputted to the second circuit block 220.

A second test output signal may be outputted from the scan output port corresponding to the test data signal inputted according to the test clock signal. The scan test may be performed based on the second test output signal.

Since the scan test is performed as the second test input signal including the test clock signal and the test data signal is provided according to a test frequency set based on the output frequency of the first test output signal which is the output signal of the process detector (or the current value or the voltage value of the first test output signal which is the output signal of the electrical parameter measurement circuit block), the scan test may be performed while a test time is reduced or damage to the semiconductor device 200 is prevented depending on the characteristics of the semiconductor device 200.

Even though an operation by the sampling circuit 110 for setting a test frequency is performed, an optimized scan test may be performed without affecting an overall test time.

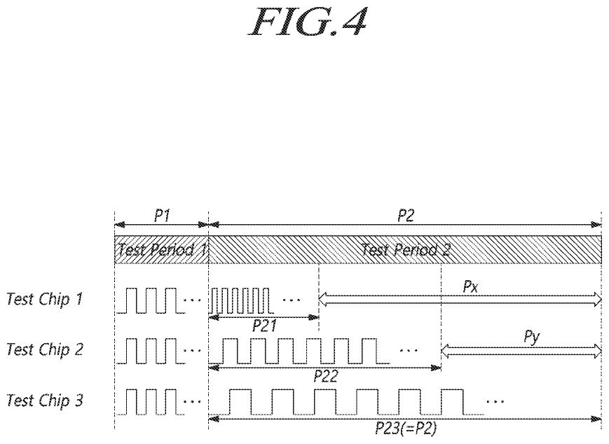

FIG. 4 is a timing diagram illustrating test input signals inputted during respective test periods for respective semiconductor chips in accordance with an embodiment of the present disclosure. FIG. 4 shows an example in which tests are performed on three semiconductor chips (test semiconductors).

Referring to FIG. 4, a test on the second circuit block 220 may be performed using a measurement value obtained through the first circuit block 210 included in the semiconductor device 200.

The sampling circuit 110 of the test apparatus 100 may output first test input signals to a first test semiconductor, a second test semiconductor and a third test semiconductor during a first test period.

The length of the first test period for the first test semiconductor, the second test semiconductor and the third test semiconductor may be the same as P1 (test period 1).

The input frequencies of the first test input signals inputted to the first test semiconductor, the second test semiconductor and the third test semiconductor may be the same.

The sampling circuit 110 may receive first test output signals outputted from the first test semiconductor, the second test semiconductor and the third test semiconductor in response to the first test input signals.

The values of output frequencies or output voltage values or output current values according to the first test output signals may be stored in the cache memory 130.

The test control circuit 120 may set test frequencies for the respective test semiconductors based on the values of the output frequencies or the output voltage values or the output current values according to the first test output signals.

For example, for the first test semiconductor, the test control circuit 120 may output a second test input signal which has a test frequency higher than the input frequency of the first test input signal.

For the second test semiconductor, the test control circuit 120 may output a second test input signal which has a test frequency lower than the input frequency of the first test input signal.

For the third test semiconductor, the test control circuit 120 may output a second test input signal which has a test frequency lower than the input frequency of the first test input signal and even lower than the test frequency of the second test input signal inputted to the second test semiconductor.

In this way, tests may be performed based on the second test input signals having different test frequencies for the respective test semiconductors. For example, scan tests may be performed at different scan shift speeds.

In a case where a test frequency is assigned by the unit of a group, the test frequencies of second test input signals for two test semiconductors whose output frequencies of first test output signals corresponding to first test input signals are different may be the same as each other.

Tests may be performed based on the second test input signals according to test frequencies optimized for the first test semiconductor, the second test semiconductor and third test semiconductor, respectively.

In the case of the first test semiconductor, since the test is performed based on the second test input signal with a high test frequency, the length of a second test period may be short as P21. Compared to a length P2 (test period 2) of an overall second test period, a test time may be reduced by a length Px.

In the case of the second test semiconductor, the test may be performed based on a test frequency that is lower than the test frequency for the first test semiconductor but is higher than a test frequency for the third test semiconductor. The length of a second test period for the second test semiconductor is P22 that may be shorter than the length P2 of the overall second test period. A test time may be reduced by a length Py.

In the case of the third test semiconductor, the test may be performed based on a low test frequency. The length of a second test period for the third test semiconductor is P23 that may be the same as P2.

In this way, the length of the second test period may be optimized for each test semiconductor. An overall test period may be reduced.

The length of the first test period may be shorter than the length of the second test period. The length of the first test period of the test semiconductors (e.g., test chips 1, 2, 3) may be same or similar. The length of the second test period of the test semiconductors (e.g., test chips 1, 2, 3) may be different, since the second test period is optimized for each of the test semiconductors. Thus, differences among the first test period of the test semiconductors may be smaller than differences among the second test period of the test semiconductors.

Even though characteristic measurement by the sampling circuit 110 is performed before the second test period, since the length of the first test period is small, it is possible to prevent an increase in an overall test time. By reducing the second test period for each test semiconductor, the test for each test semiconductor may be normally performed, and the overall test time may be reduced.

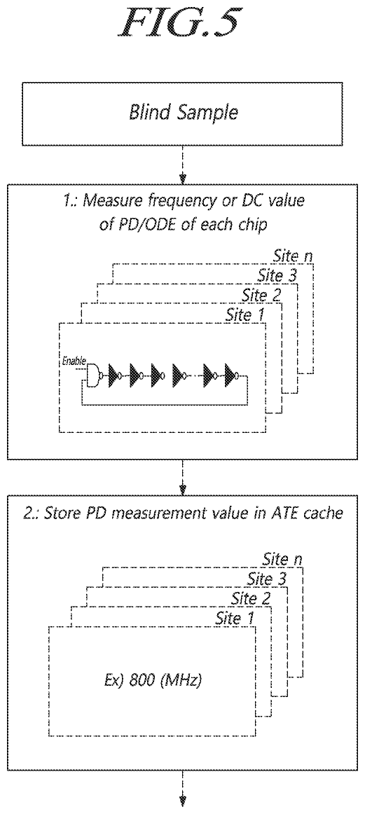

FIGS. 5 to 8 are diagrams for describing a method for testing a semiconductor chip in accordance with an embodiment of the present disclosure.

Referring to FIG. 5, the output frequency of a process detector (PD) circuit block or the output voltage/current value (i.e., DC value) of an electrical parameter measurement circuit block (e.g., an on-die EPM (ODE)) for each of a plurality of test semiconductors may be measured by the test apparatus 100. A blind sample may mean the test semiconductors that a test by the test apparatus 100 is not performed yet.

The test apparatus 100 may store the output frequency or the output voltage/current value obtained from each of the plurality of test semiconductors in the cache memory 130.

For example, when using the process detector circuit block included in each of the plurality of test semiconductors, an output frequency value may be stored in the cache memory (i.e., ATE cache) 130. The output frequency value for each of the plurality of test semiconductors may be stored in the cache memory 130 to be used in classifying each of the test semiconductors.

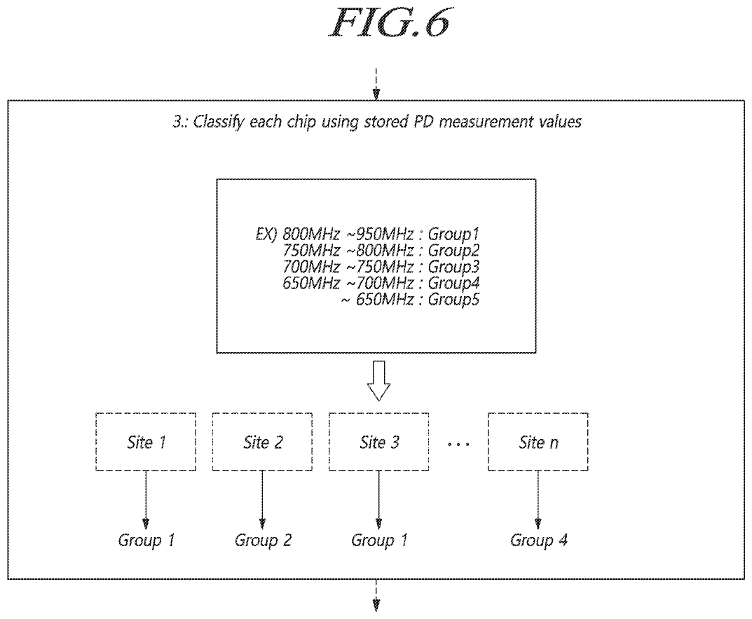

For example, referring to FIG. 6, groups may be set depending on the range of output frequency values. FIG. 6 shows as an example a case where groups are set for five ranges. A test semiconductor may be classified into a first group when an output frequency value is 800 MHz to 950 MHz, may be classified into a second group when an output frequency value is 750 MHz to 800 MHz, may be classified into a third group when an output frequency value is 700 MHz to 750 MHz, may be classified into a fourth group when an output frequency value is 650 MHz to 700 MHz, and may be classified into a fifth group when an output frequency value is equal to or less than 650 MHz.

According to output frequency values obtained from a plurality of test semiconductors, each test semiconductor may be classified into one of the five preset groups. For example, a first test semiconductor, a second test semiconductor, a third test semiconductor and an nth test semiconductor may be classified into a first group, a second group, a third group and a fourth group, respectively, according to output frequency values.

As the groups of the plurality of test semiconductors are classified, test frequencies set for the corresponding groups may be applied. When a scan test is performed, a scan shift speed for each test semiconductor may be set.

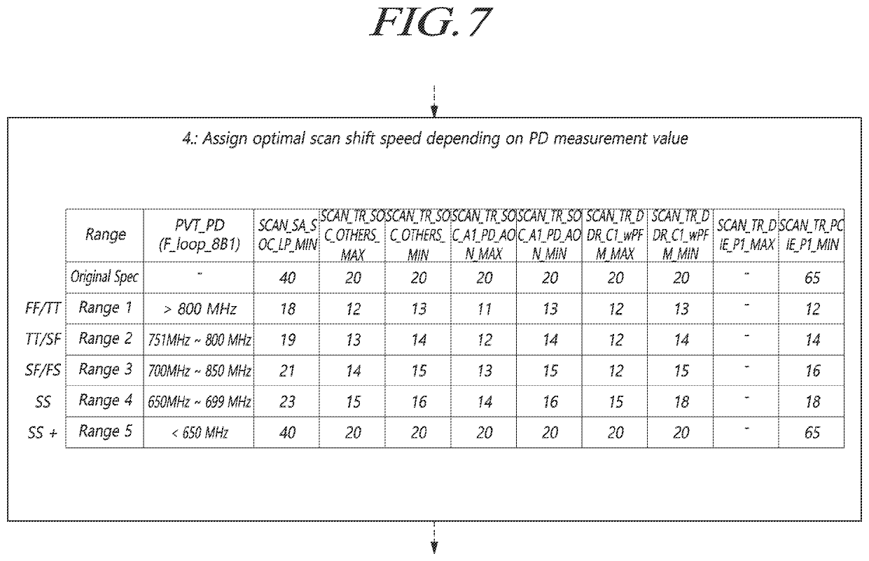

For example, referring to FIG. 7, examples of scan shift speeds are shown. When a scan shift speed set originally (or in default) is, for example, 40, 20, 20, 20, 20, 20, 20 and 65, a scan shift speed for a test semiconductor belonging to the fifth group (Range 5) with a lowest output frequency may be set to be the same as the value set originally (or in default).

As an output frequency increases, a time according to a scan shift speed set for a corresponding group may decrease. The scan shift speed for the corresponding group may increase. A test frequency for the corresponding group may increase. As an output frequency increases, a faster scan shift speed and a higher test frequency may be assigned.

A scan test may be performed when a scan shift speed set for a group to which a plurality of test semiconductors belong is assigned.

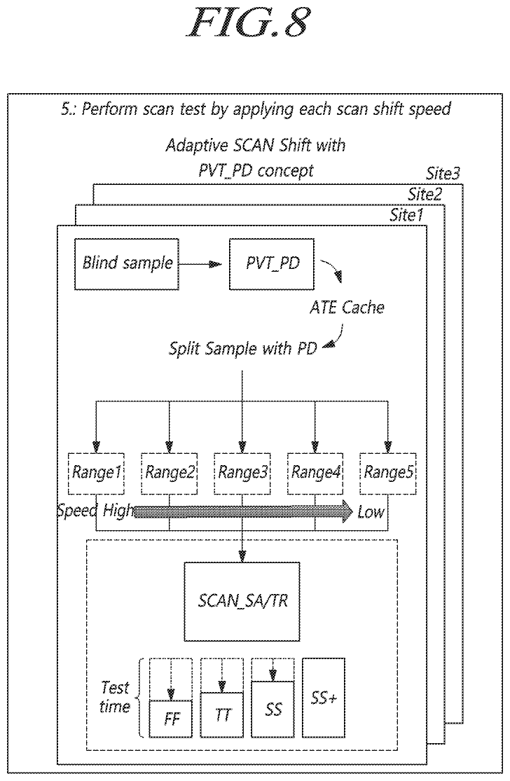

For example, referring to FIG. 8, a scan shift speed may be assigned according to a group classified based on an output frequency value obtained through a process detector circuit block. A scan test for each test semiconductor may be performed according to the assigned scan shift speed.

A scan test may be performed at a fastest scan shift speed for a test semiconductor belonging to the first group. A time during which the scan test on the test semiconductor belonging to the first group is performed may be reduced.

Scan shift speeds assigned to test semiconductors belonging to the second group, the third group and the fourth group may be smaller than the scan shift speed assigned to the test semiconductor belonging to the first group, and may be larger than a scan shift speed assigned to a test semiconductor belonging to the fifth group.

Times required for the scan tests on the test semiconductors belonging to the second group, the third group and the fourth group may be greater than the time required for the scan test on the test semiconductor belonging to the first group, and may be less than a time required for the scan test on the test semiconductor belonging to the fifth group. The times required for the scan tests on the test semiconductors belonging to the second group, the third group and the fourth group may also be reduced.

Since the time required for the scan test on the test semiconductor belonging to the fifth group maintains the default set value, damage to the test semiconductor due to the scan test may be prevented.

According to the embodiment of the present disclosure, since a test is performed on the second circuit block 220 using a test frequency set by reflecting the characteristic measurement value of the first circuit block 210 included in the semiconductor device 200, an optimized test may be performed on each semiconductor device 200.

Overall test performance may be improved by reducing a time required for a test on the semiconductor device 200 while stably performing the test.

Although various embodiments of the present disclosure have been described with particular specifics and varying details for illustrative purposes, those skilled in the art will appreciate that various modifications, additions and substitutions may be made based on what is disclosed or illustrated in the embodiments of the present disclosure without departing from the spirit and scope of the present disclosure as defined in the following claims. Furthermore, the embodiments may be combined to form additional embodiments.

What is claimed is:

1. A test apparatus comprising:
a sampling circuit configured to output, during a first test period, a first test input signal to a first circuit block included in each of a plurality of semiconductor devices to be tested, and receive a first test output signal outputted from the first circuit block; and
a test control circuit configured to output, during a second test period, a second test input signal having a test frequency set for each of the plurality of semiconductor devices, corresponding to an output frequency or an output current value of the first test output signal to a second circuit block included in each of the plurality of semiconductor devices, and perform a test on each of the plurality of semiconductor devices.

2. The test apparatus according to claim 1, wherein the test control circuit classifies each of the plurality of semiconductor devices into one of N number of preset groups based on the output frequency or the output current value of the first test output signal, and performs a test on each of the plurality of semiconductor devices using the second test input signal having the test frequency set for each of the N number of preset groups, where N is a natural number 2 or more.

3. The test apparatus according to claim 1, wherein a length of the first test period is less than a length of the second test period.

4. The test apparatus according to claim 1, wherein the test frequency is set in proportion to the output frequency or the output current value of the first test output signal.

5. The test apparatus according to claim 1, wherein a length of the second test period is inversely proportional to the output frequency or the output current value of the first test output signal.

6. The test apparatus according to claim 1, wherein:
an input frequency of the first test input signal inputted to a first semiconductor device among the plurality of semiconductor devices is equal to an input frequency of the first test input signal inputted to a second semiconductor device; and
the test frequency of the second test input signal inputted to the first semiconductor device is different from the test frequency of the second test input signal inputted to the second semiconductor device.

7. The test apparatus according to claim 1, wherein:
a length of the first test period for a first semiconductor device among the plurality of semiconductor devices is equal to a length of the first test period for a second semiconductor device; and
a length of the second test period for the first semiconductor device is different from a length of the second test period for the second semiconductor device.

8. The test apparatus according to claim 1, wherein:
the output frequency or the output current value of the first test output signal of a first semiconductor device among the plurality of semiconductor devices is greater than the output frequency or the output current value of the first test output signal of a second semiconductor device; and
the test frequency of the second test input signal inputted to the first semiconductor device is greater than the test frequency of the second test input signal inputted to the second semiconductor device.

9. The test apparatus according to claim 8, wherein:
the output frequency or the output current value of the first test output signal of a third semiconductor device among the plurality of semiconductor devices is less than the output frequency or the output current value of the first test output signal of the first semiconductor device, and is greater than the output frequency or the output current value of the first test output signal of the second semiconductor device; and
the test frequency of the second test input signal inputted to the third semiconductor device is identical to the test frequency of the second test input signal inputted to the first semiconductor device or the test frequency of the second test input signal inputted to the second semiconductor device.

10. The test apparatus according to claim 1, wherein the first test input signal comprises a first test clock signal, and the second test input signal comprises a second test clock signal and a test data signal.

11. The test apparatus according to claim 1, further comprising:
a cache memory configured to store the output frequency or the output current value of the first test output signal obtained by the sampling circuit.

12. The test apparatus according to claim 1, wherein the first circuit block includes a process detector circuit block, and the second circuit block includes a scan test circuit block.

13. The test apparatus according to claim 1, wherein the first circuit block includes an electrical parameter measurement circuit block, and the second circuit block includes a scan test circuit block.

14. A semiconductor device comprising:
a first circuit block configured to externally receive a first test input signal and output a first test output signal during a first test period; and
a second circuit block configured to externally receive a second test input signal which has a test frequency set corresponding to an output frequency or an output current value of the first test output signal, during a second test period.

15. The semiconductor device according to claim 14, wherein a length of the first test period is less than a length of the second test period.

16. The semiconductor device according to claim 14, wherein the test frequency is set in proportion to the output frequency or the output current value of the first test output signal.

17. The semiconductor device according to claim 14, wherein a length of the second test period is inversely proportional to the output frequency or the output current value of the first test output signal.

18. The semiconductor device according to claim 14, wherein the first test input signal comprises a first test clock signal, and the second test input signal comprises a second test clock signal and a test data signal.

19. A method for testing a semiconductor chip, the method comprising:
transmitting, during a first test period, a first test input signal to a first circuit block included in each of a plurality of semiconductor devices;
receiving a first test output signal outputted from the first circuit block;
classifying each of the plurality of semiconductor devices into one of N number of preset groups based on an output frequency or an output current value of the first test output signal; and
transmitting, during a second test period, a second test input signal which has a test frequency set for each of the N number of preset groups to a second circuit block included in each of the plurality of semiconductor devices, where N is a natural number 2 or more.

20. The method according to claim 19, wherein a length of the first test period is less than a length of the second test period, and a deviation of the first test period for each of the plurality of semiconductor devices is less than a deviation of the second test period for each of the plurality of semiconductor devices.
